(19) United States
(12) Patent Application Publication
(10) Pub. No.: US 2026/0047381 A1
(43) Pub. Date: Feb. 12, 2026

(54) SUBSTRATE PROCESSING APPARATUS

(71) Applicant: SAMSUNG ELECTRONICS CO., LTD., Suwon-si (KR)

(72) Inventors: Jinoh Im, Suwon-si (KR); Ilyoung Yoon, Suwon-si (KR)

(21) Appl. No.: 19/050,975

(22) Filed: Feb. 11, 2025

(30) Foreign Application Priority Data
Aug. 12, 2024 (KR) 10-2024-0107784

(51) Int. Cl. H01L 21/67; B24B 37/005; H01L 21/677

(52) U.S. Cl. CPC H01L 21/67253; B24B 37/005; H01L 21/67703

(57) ABSTRACT

A substrate processing apparatus includes a substrate having first points and second points different from the first points, a measurement module configured to measure at least one thickness of the substrate, a substrate processor configured to perform a planarization process on the substrate, and a controller configured to control the substrate processor based on thickness information of the substrate measured by the measurement module. The controller is configured to control the substrate processor to planarize the first points based on first thickness information of the substrate including first thicknesses measured at the first points and to control the substrate processor to planarize the second points based on second thickness information of the substrate including second thicknesses measured at the second points.

### CROSS-REFERENCE TO RELATED APPLICATIONS

This application claims priority to Korean Patent Application No. 10-2024-0107784, filed in the Korean Intellectual Property Office on Aug. 12, 2024, the entire contents of which are hereby incorporated by reference.

### BACKGROUND

The surface step height of semiconductor wafers is increasing due to increasing density, miniaturization, and multilayering of wiring structures of semiconductor devices. For the higher performance of the semiconductor devices such as contact between wires, etc., methods such as chemical mechanical polishing (CMP), etc. can be used to planarize the surface step height. Recently, a planarization process by irradiating a laser beam onto the surface of the semiconductor wafer has been studied and used.

### SUMMARY

In order to solve one or more problems (e.g., the problems described above and/or other problems not explicitly described herein), the present disclosure provide a substrate processing apparatus capable of improving manufacturing efficiency of semiconductor devices.

In order to solve one or more problems (e.g., the problems described above and/or other problems not explicitly described herein), the present disclosure also provides a substrate processing apparatus capable of locally planarizing a wafer surface.

According to some aspects of the present disclosure, a substrate processing apparatus may include a substrate having first points and second points different from the first points, a measurement module configured to measure at least one thickness of the substrate, a substrate processor configured to perform a planarization process on the substrate, and a controller configured to planarize the first points based on first thickness information of the substrate, the first thickness information including first thicknesses measured at the first points of the substrate by the measurement module, and control the substrate processor to planarize the second points based on second thickness information of the substrate, the second thickness information including second thicknesses measured at the second points of the substrate by the measurement module.

According to some aspects, a substrate processing apparatus may include a loader configured to receive a substrate having first points and second points different from the first points is loaded, a measurement module connected to the loader and configured to measure first and second thickness information of the substrate loaded into the loader, a substrate processor connected to the loader and configured to perform a planarization process using a beam on the substrate for which a thickness has been measured by the measurement module, a substrate transferer and configured transfer the substrate from the loader to the measurement module or to the substrate processor, and a controller configured to control a first time for planarizing the first points by the substrate processor based on the first thickness information of the substrate including first thicknesses measured at the first points, and control a time for planarizing the second points by the substrate processor based on the second thickness information of the substrate including second thicknesses measured at the second points.

According to some aspects, a substrate processing apparatus may include a substrate having first points and second points different from the first points, a measurement module configured to measure thickness information of the substrate, a first substrate processor configured to perform a planarization process using a beam on the substrate for which thicknesses have been measured by the measurement module, a second substrate processor configured to process the substrate planarized by the first substrate processor, and a controller configured to control a first time for planarizing the first points by the substrate processor based on first thickness information of the substrate, the first thickness information including first thicknesses measured at the first points, and control a second time for planarizing the second points by the substrate processor based on estimated thickness information of the substrate estimated at the first points and second thickness information of the substrate, the second thickness information including second thicknesses measured the second points.

According to some aspects of the present disclosure, the substrate processing apparatus can improve the manufacturing efficiency of semiconductor devices by improving the progress speed of the planarization process.

According to some aspects, the substrate processing apparatus can perform the local planarization of the wafer surface.

### BRIEF DESCRIPTION OF THE DRAWINGS

The above and other objects, features and advantages of the present disclosure will become more apparent to those of ordinary skill in the art by describing in detail example implementations thereof with reference to the accompanying drawings, in which:

FIG. 1 is a diagram provided to explain a substrate processing apparatus;

FIG. 2 is a control block diagram of the substrate processing apparatus;

FIG. 3 is a flowchart provided to explain a substrate processing method of the substrate processing apparatus;

FIG. 4 is a flowchart provided to explain a method for locally planarizing the substrate;

FIGS. 5 and 6 are diagrams provided to explain a method for measuring a thickness of the substrate;

FIGS. 7 and 8 are diagrams provided to explain a local planarization method;

FIGS. 9 and 10 are diagrams provided to explain a method for measuring a thickness of the substrate;

FIGS. 11 to 13 are flowcharts provided to explain a method for locally planarizing the substrate according to some aspects;

FIG. 14 is a diagram provided to explain the substrate processing apparatus; and

FIG. 15 is a diagram provided to explain a method for transferring the substrate.

### DETAILED DESCRIPTION

Hereinafter, a substrate processing apparatus according to some aspects will be described in detail with reference to the drawings.

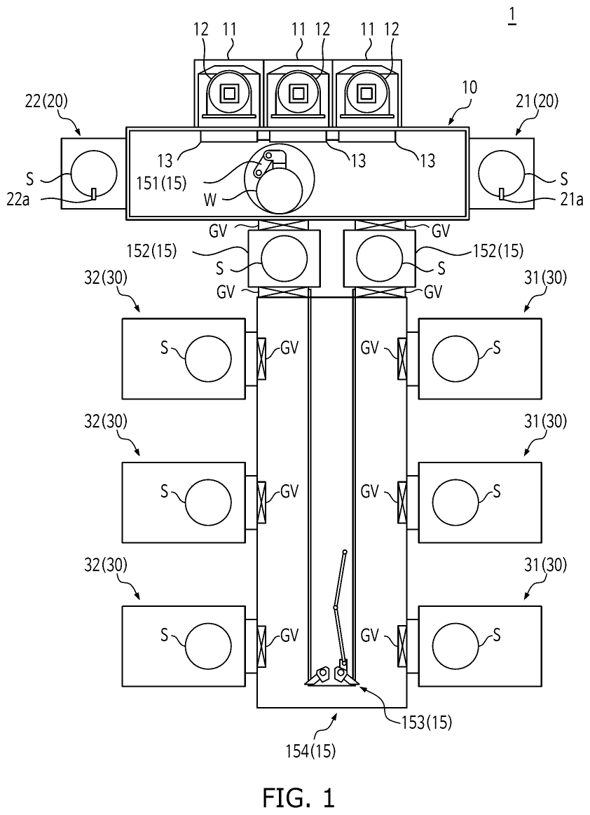

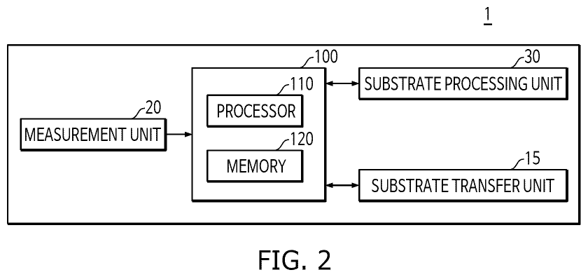

FIG. 1 is a diagram provided to explain a substrate processing apparatus. FIG. 2 is a control block diagram of the substrate processing apparatus.

Referring to FIGS. 1 and 2, the substrate processing apparatus may include a loading unit 10, a substrate transfer unit 15, a measurement unit 20, a substrate processing unit 30, and a controller 100.

The loading unit 10 may receive a substrate W. The loading unit 10 may load the substrate W into a substrate processing apparatus 1. The loading unit 10 may be provided with carriers 11 and carrier supports 12 that support the carriers 11. The carriers 11 may accommodate the substrates W such as semiconductor wafers. The carrier 11 may include a Front Opening Unified Pod (FOUP), a Front Opening Shipping Box (FOSB), etc. The wafer carriers 11 may be disposed on the carrier supports 12. For example, three wafer carriers 11 and three carrier supports 12 may be disposed, but aspects are not limited thereto.

The loading unit 10 may be provided with an input port 13 for the substrate W corresponding to each carrier support 12. The substrate transfer unit 15 for transferring the substrate W disposed inside the carrier 11 may be disposed on the loading unit 10. For example, a transfer arm 151 for loading the substrate W may be disposed. The transfer arm 151 may take out the substrate W from the carrier 11 through the input port 13. The transfer arm 151 may transfer the substrate W to the measurement unit 20, the substrate processing unit 30, etc.

The measurement unit 20 may be disposed on one side of the loading unit 10. The measurement unit 20 may measure the substrate W loaded in the loading unit 10. For example, the measurement unit 20 may measure surface state, position, thickness information, etc. of the substrate W.

The measurement unit 20 may include a first measurement unit 21 and a second measurement unit 22. Each of the first measurement unit 21 and the second measurement unit 22 may include a stage S on which the substrate Wis seated. For example, the transfer arm 151 may transfer the substrate W onto the stage S. The first measurement unit 21 and the second measurement unit 22 may measure information on the substrate W seated on the stage S. The first measurement unit 21 and the second measurement unit 22 may include optical sensors 21a and 22a, respectively. The optical sensors 21a and 22a may measure a surface shape of the substrate W, position information of the substrate W, etc. For example, the optical sensors 21a and 22a may include at least one of an optical interferometry, a triangulation sensor, a confocal microscopy, and a gap sensor. However, aspects are not limited thereto.

The first measurement unit 21 and the second measurement unit 22 may measure thickness information of the substrate at a plurality of points on the substrate W. For example, the first measurement unit 21 and the second measurement unit 22 may include at least one of the optical interferometry, a spectrometer, a spectroscopic ellipsometry, and a spectral reflectometry. However, aspects are not limited thereto.

The first measurement unit 21 and the second measurement unit 22 may have the same configuration. For example, the first measurement unit 21 and the second measurement unit 22 may be devices including an optical interferometer. However, aspects are not limited thereto.

The substrate transfer unit 15 may include a moving port 152. The substrate W may be moved from the loading unit 10 to the substrate processing unit 30 through the moving port 152. The substrate W on which measurement has been completed by the measurement unit 20 may be transferred to the substrate processing unit 30 through the moving port 152. Gate valves GV may be provided on both sides of the moving port 152. The gate valve GV adjacent to the loading unit 10 may maintain the atmospheric pressure, and the gate valve GV adjacent to the substrate processing unit 30 may maintain the vacuum. For example, the moving port 152 may include a load lock unit. The load lock unit may convert an atmospheric pressure state into a vacuum state. That is, the loading unit 10 may be in the atmospheric pressure state, and the substrate processing unit 30 may be in the vacuum state.

The substrate W that passes through the moving port 152 may be moved to the substrate processing unit 30 by a transfer arm 153 disposed on a transfer base 154. A transfer rail may be provided on the transfer base 154 to allow the transfer arm 153 to be moved. That is, the transfer arm 153 may be moved along the transfer rail and transfer the substrate W. For example, the transfer arm 153 may have a linkage structure for the substrate W.

The substrate processing unit 30 may provide a space for processing the substrate W. The substrate processing unit 30 may perform substrate processing such as planarization, etching, ashing, ion implantation, thin film deposition, cleaning, etc., but is not limited thereto. The substrate processing unit 30 may be disposed on one side of the transfer base 154. Each substrate processing unit 30 may include a stage S on which the substrate W transferred by the transfer arm 153 is seated. The substrate W may be processed while seated on the stage S.

The substrate processing unit 30 may include a first substrate processing unit 31 and a second substrate processing unit 32 that perform different processes. For example, the first substrate processing unit 31 may perform a planarization process. The second substrate processing unit 32 may process the planarized substrate. For example, the second substrate processing unit 32 may perform an etching process. However, aspects are not limited thereto, and the substrate processing unit 30 may perform other unit processes or perform two or more unit processes. The first substrate processing unit 31 may be disposed on one side of the transfer base 154, and the second substrate processing unit 32 may be disposed on the other side of the transfer base 154. Each of the first substrate processing unit 31 and the second substrate processing unit 32 may include a plurality of substrate processing units. Each of the first substrate processing unit 31 and the second substrate processing unit 32 may include three substrate processing units.

In some aspects, the planarization process may include at least one of a local selective planarization process and a global planarization process of the substrate.

The substrate processing unit 30 may planarize at least a portion of the substrate W using a beam. The substrate processing unit 30 may planarize a partial region of the substrate W by irradiating a beam toward the substrate W. The beam may move across and scan the substrate W. For example, the beam may partially planarize the substrate W while moving slowly on a thick portion of the substrate W and moving rapidly on a thin portion of the substrate W.

In another aspect, the substrate processing unit 30 may use a polishing pad to planarize at least a portion of the substrate W. The substrate processing unit 30 may planarize a partial region of the substrate W by using a method of physically or mechanically polishing the substrate W with the polishing pad. For example, the polishing pad may be rotated and press against the substrate W to polish the surface of the substrate W, and may be moved across the substrate W so that the substrate W is planarized. The polishing pad may be rotated rapidly or press strongly on a thick portion of the substrate W, and may be rotated slowly or press weakly on a thin portion of the substrate W.

In addition, slurry, etc. may be supplied onto the substrate W so that chemical polishing is performed together while the polishing pad planarizes at least a portion of the substrate W. That is, the substrate processing unit 30 may planarize the substrate W by the mechanical chemical polishing (CMP) process.

The controller 100 may control the substrate processing unit 30 and/or the substrate transfer unit 15 based on the thickness information of the substrate W measured by the measurement unit 20. The controller 100 may control the substrate processing method of the substrate processing unit 30 based on the thickness information of the substrate W measured by the measurement unit 20. For example, if the thickness of a portion of the substrate W measured by the measurement unit 20 is thicker than a target value, the intensity of the beam may be increased or the time during which the beam is irradiated may be increased.

The controller 100 may control the substrate processing method of the substrate transfer unit 15 based on the thickness information of the substrate W measured by the measurement unit 20. For example, if the thickness of the substrate W measured by the measurement unit 20 reaches the target value, the substrate W may be transferred to another substrate processing unit 30 for the next substrate processing.

The controller 100 may include a memory 120 that stores a program and various types of data for executing the operations already described above or to be described below, and a processor 110 that processes data by executing the program stored in the memory 120.

The memory 120 may include at least one of a volatile memory such as a static random access memory (SRAM), a dynamic random access memory (DRAM), etc., and a non-volatile memory such as a flash memory, a read only memory (ROM), an erasable programmable read only memory (EPROM), an electrically erasable programmable read only memory (EPROM), etc.

The non-volatile memory may operate as an auxiliary memory of the volatile memory and may retain stored data even if power of the substrate processing apparatus is cut off. For example, the non-volatile memory may store control programs and control data for controlling the operation of the substrate processing apparatus or the operation of the measurement unit.

Unlike the non-volatile memory, the volatile memory may lose the stored data if power of the substrate processing apparatus is cut off. The volatile memory may load a control program and control data from the non-volatile memory and temporarily store the control program and control data, temporarily store an input setting value or control command, or temporarily store a control signal, etc. output from the processor 110.

The processor 110 may process data or output a control signal according to the program stored in the memory 120. For example, the processor 110 may process data or output a control signal according to a program including instructions for executing a control method based on substrate thickness information, etc. stored in the memory 120.

The processor 110 and the memory 120 may be provided in a single configuration or may be provided in a plurality of configurations according to their capacities. In addition, the processor 110 and the memory 120 may be physically separated or may be provided as a single chip.

The substrate processing method executed by the controller 100 will be described in detail below.

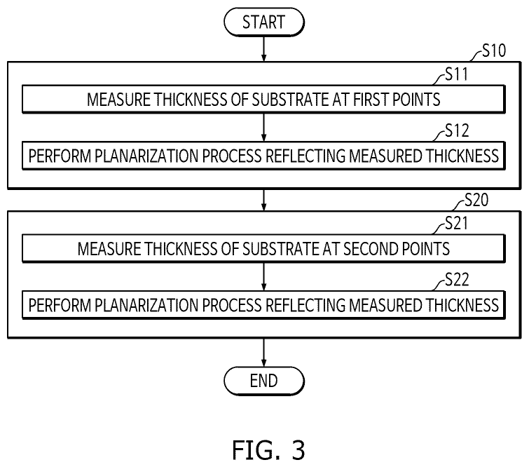

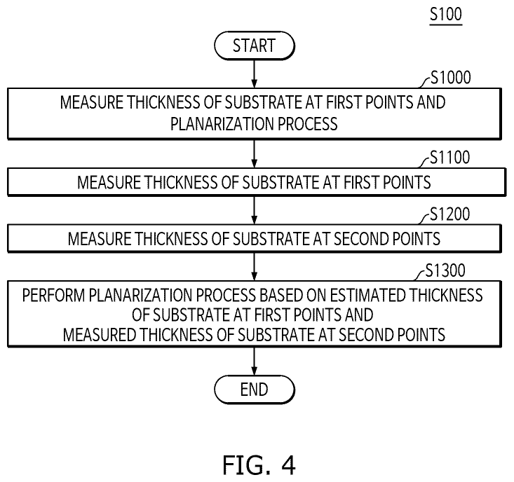

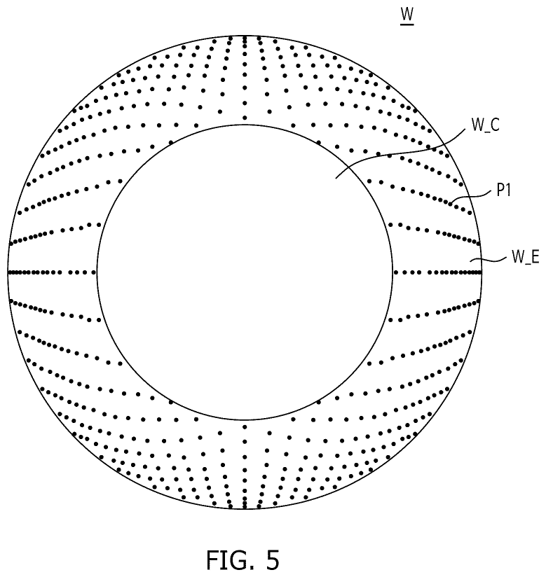

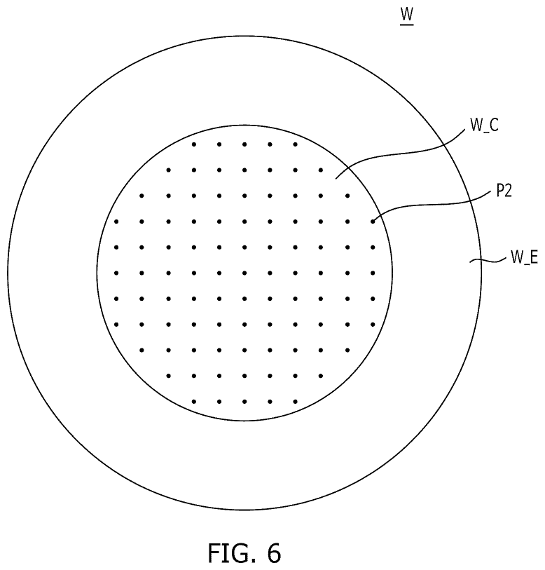

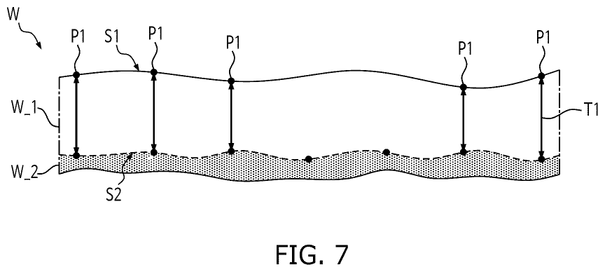

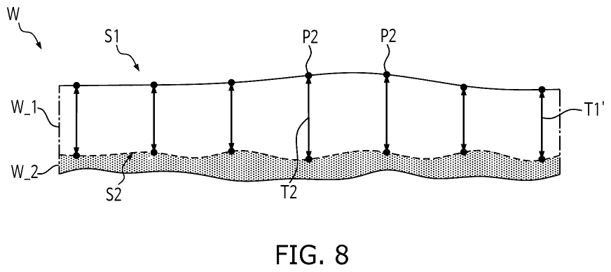

FIG. 3 is a flowchart provided to explain a substrate processing method of the substrate processing apparatus. FIG. 4 is a flowchart provided to explain a method for locally planarizing the substrate. FIGS. 5 and 6 are diagrams provided to explain a method for measuring a thickness of the substrate. FIGS. 7 and 8 are diagrams provided to explain a local planarization method.

Referring to FIGS. 3 and 4, the substrate processing method may include a sequence of a first operation S10 and a second operation S20.

If the aspect is implemented differently, a specific sequence of the processes may be performed differently from the order described herein. For example, two processes described in succession may be performed substantially simultaneously, or may be performed in the opposite order to the order described.

The first operation S10 may include an operation S11 of measuring the thickness of the substrate at first points. The measurement unit may measure the thickness of the substrate at first points of the substrate. That is, the thickness of the substrate may be measured at each position of the first points. The thickness information of the substrate measured at the first points may be stored in the memory of the controller.

The first operation S10 may include an operation S12 of performing a planarization process taking into account the thickness measured at the first points. The controller may control the planarization process at the substrate processing unit based on the thickness information of the substrate measured at the first points. The controller may take into account the measured thickness information of the substrate and control the substrate processing unit to perform the planarization process. The substrate processing unit may control the planarization process of the substrate based on the thickness information of the substrate from the controller. For example, in proportion to the thickness of the substrate, the substrate processing unit may increase the intensity of the irradiated beam or increase the time of beam irradiation.

In the substrate processing apparatus according to some aspects, the controller may control the time for planarizing the first points by the substrate processing unit based on the thickness information of the substrate measured at the first points. For example, the controller may control the substrate processing apparatus such that the thickness of the substrate measured at the first points by the measurement unit is proportional to the time for planarizing the first points by the substrate processing unit.

After the first operation S10 is performed, the controller may additionally control the thickness distribution of the substrate. For example, if the thickness distribution of the substrate is poor even after the planarization process performed in the first operation S10, an additional planarization process may be performed. In this case, the operation of measuring the thickness of the region already locally planarized in the first operation S10 may be omitted such that the process efficiency may be improved.

With the substrate processing method according to some aspects, the second operation S20 may be performed after the first operation S10 is completed. The second operation S20 may include an operation S21 of measuring the thickness of the substrate at second points. The measurement unit may measure the thickness of the substrate at the second points of the substrate. That is, the thickness of the substrate may be measured at each of the second points. The thickness information of the substrate measured at the second points may be stored in the memory of the controller.

The second points may be different from the first points. That is, the second points may not overlap the first points. The number of the second points may be less than the number of the first points, but aspects are not limited thereto.

Because the thickness information of the substrate measured at the first points is stored, the thickness of the substrate may be measured only at the second points. Accordingly, because the thickness of the substrate at the first points is not measured in the second operation S20, the speed of the thickness measurement of the substrate may be increased. Since the number of the second points is less than the number of the first points, the operation S21 of measuring the thickness of the substrate in the second operation S20 may proceed faster than the operation S11 of measuring the thickness of the substrate in the first operation S20.

The second operation S20 may include an operation S22 of taking into account the thickness measured at the second points and performing a planarization process. The controller may control the planarization process at the substrate processing unit based on the thickness information of the substrate measured at the second points. The controller may automatically take into account the measured thickness information of the substrate and control the substrate processing unit to perform the planarization process. The substrate processing unit may control the planarization process of the substrate based on the thickness information of the substrate from the controller. For example, in proportion to the thickness of the substrate, the substrate processing unit may increase the intensity of the irradiated beam or increase the time of beam irradiation.

In the substrate processing apparatus according to some aspects, the controller may control the time for planarizing the second points by the substrate processing unit based on the thickness information of the substrate measured at the second points. The controller may control the time for planarizing the second points by the substrate processing unit further based on the thickness information of the substrate estimated at the first points.

For example, the controller may control the apparatus such that the thickness of the substrate measured at the second points by the measurement unit is proportional to the time for planarizing the second points by the substrate processing unit.

Although it is illustrated that the substrate processing method includes the first operation S10 and the second operation S20, aspects are not limited thereto. After performing the second operation S20, an additional planarization process for controlling the thickness distribution of the substrate may be required. That is, the substrate processing method may include an operation of additionally measuring a thickness of the substrate and an operation of performing a planarization process based on substrate thickness information.

With the substrate processing method according to some aspects, the operation S12 of performing the planarization process taking into account the thickness measured at the first points may correspond to a speed determining operation. That is, since the time required in the operation S12 of performing the planarization process taking into account the thickness measured at the first points accounts for a high proportion of the substrate processing time, the operation S12 of performing the planarization process may be considered as a major factor in determining the speed of the process. For example, by giving significant consideration to the speed determining operation, the unit per equipment hour (UPEH) of the substrate processing apparatus may be easily improved.

Referring to FIG. 4, a local planarization method S100 of the substrate according to some aspects may include first to fourth operations S1000 to S1300.

The method S100 may include an operation S1000 of measuring a thickness of a substrate at first points and performing a planarization process. The thickness of the substrate may be measured at the first points, and the planarization process may be performed based on the thickness information of the substrate measured at the first points.

The method S100 may include an operation S1100 of estimating the thickness of the substrate at the first points. Since the planarization process is performed at the first points, the substrate thickness at the first points may be reduced. If the thickness of the substrate is measured again at the first points, the substrate processing time may increase. That is, the substrate processing speed may decrease, which may lower process efficiency. Therefore, the thickness of the substrate may be estimated at the first points before performing a third operation S1200 and a fourth operation S1300, and after the planarization process in the second operation S1100. The thickness of the substrate at the estimated first points may be stored in a memory.

The method S100 may include the operation S1200 of measuring the thickness of the substrate at second points. In order to measure the thickness of the substrate at the second points, the thickness of the substrate at the first points estimated in the second operation S1100 may be taken into account. The first points may be portions where the planarization of the substrate is performed. On the other hand, the second points may be portions where the local planarization of the substrate is not performed. Therefore, the thickness of the substrate may be measured at the second points different from the first points.

The method S100 may include the operation S1300 of measuring the thickness of the substrate estimated at the first points and the thickness of the substrate measured at the second points and performing the planarization process. After the planarization process is performed at the first points, the thickness of the substrate may be estimated at the first points. For example, the estimated thickness of the substrate at the first points may be close to the target value. The planarization of the substrate may be performed at the second points based on the thickness of the substrate estimated at the first points and the thickness of the substrate measured at the second points. That is, since the thickness of the substrate may be estimated without measuring the thickness of the substrate at the first points again, the measurement time of the thickness of the substrate may be reduced. Since the local planarization of the substrate is performed at the second points excluding the first points in the planarization process at the second points, the speed of the planarization process, etc. may increase. That is, the time required for the planarization process may be reduced, and the efficiency of the planarization process may be improved.

Referring to FIGS. 5 and 6, the substrate W may be a circular semiconductor wafer. The substrate W may be a silicon substrate or may include other materials, such as silicon germanium (SiGe), silicon germanium on insulator (SGOI), indium antimony, lead telluride compound, indium arsenide, indium phosphide, gallium arsenide, or gallium antimony. However, aspects are not limited thereto.

The substrate W according to some aspects may include a center region W_C and an edge region W_E. The center region W_C may be a region including a center of the substrate W. The edge region W_E may be formed along the periphery of the substrate W. The center region W_C and the edge region W_E may be defined according to positions relative to each other, and each of the shapes, areas, ratios, etc. may be variously formed. For example, the area occupied by the center region W_C may be larger and the area occupied by the edge region W_E may be smaller. Alternatively, the shape of the center region W_C may be a square, and the shape of the edge region W_E may be a shape surrounding the center region W_C. However, this is only an example, and the center region W_C and the edge region W_E may be variously configured. In addition, various regions forming the substrate W may be divided by various methods other than dividing into two regions as discussed above. In another aspect, the substrate W may be divided into a center region, a middle region, and an edge region.

The substrate W according to some aspects may have a plurality of points for measuring the thickness of the substrate or performing the planarization process. For example, first points P1 may be positioned on the edge region W_E, and second points P2 may be positioned on the center region W_C. This is only an example, and the first points P1 and the second points P2 may be distributed over the entire region of the substrate W. The first points P1 and the second points P2 may be disposed in the center region W_C and the edge region W_E, respectively.

The first points P1 positioned on the edge region W_E may be disposed at narrow gaps as the distance from the center of the substrate W increases. In other words, the first points P1 may be disposed at narrower gaps as they are closer to the periphery of the substrate W. The density of the first points P1 may increase toward the periphery of the substrate W.

The second points P2 positioned on the center region W_C may be disposed at regular gaps. The gaps between the second points P2 may be wider than the gaps between the first points P1. The number of second points P2 may be less than the number of first points P1.

In another aspect, the first points P1 may be disposed at narrow gaps toward the periphery of the substrate W, and the second points P2 may be disposed at regular gaps on the substrate W and may be distributed over the entire region of the substrate W. That is, the first points P1 and the second points P2 may be disposed in various distributions as long as they are points at different positions.

Referring to FIGS. 7 and 8, a second layer W_2 may be disposed on a first layer W_1. The second layer W_2 may represent an active component of a chip including a transistor, etc. formed on the first layer W_1. In another aspect, the second layer W_2 may include active components of the chip and a signal wiring component connecting the active components. In this case, one surface (e.g., a first surface of the first layer) of the first layer W_1 may be a surface on which a power wiring component for supplying power to the active component, etc. is disposed, and the other surface of the first layer W_1 (e.g., a second surface of the first layer) may be a surface on which the second layer W_2 is disposed.

The first layer W_1 may include a first surface S1 and a second surface S2 disposed in a direction opposite to the first surface S1. The first surface S1 of the first layer W_1 may be a surface on which the active structure is not formed. In addition, the second layer W_2 may be disposed on the second surface S2 of the first layer W_1. In this case, the second surface of the first layer W_1 may not be exposed to the outside. For example, the first layer W_1 may be a non-patterned substrate or a patterned substrate patterned on at least one surface.

The controller may generate a thickness map including substrate thickness information by using the thickness information of the substrate at the first points received from the measurement unit. The thickness map may include a vertical distance between surface position information (e.g., first surface profile information) of the one surface of the first layer W_1 and surface position information (e.g., second surface profile information) of the other surface of the first layer W_1. For example, the thickness map may refer to a set of vertical distance values between data points included in one surface position information and data points included in another surface position information.

The controller may receive, from the measurement unit, first surface profile information including information on the entire surface position of the first surface S1 of the first layer W_1. In addition, the controller may receive, from the measurement unit, thickness information of the substrate including the thickness of the first layer W_1 measured at the first points P1 of the first surface S1 of the first layer W_1. The controller may generate a thickness map including total thickness information (substrate thickness information) of the first layer W_1 based on the first surface profile information and the thickness information of the substrate.

The controller may receive, from the measurement unit, the first surface profile information indicating the entire surface position information of the first surface of the first layer W_1. In addition, the controller may receive, from the measurement unit, second layer W_2 profile information indicating the entire surface position information of the surface of the second layer W_2. In addition, the controller may receive, from a second measurement device, a plurality of pieces of thickness information including a sample thickness of the first layer W_1 measured at the first points P1 of the first surface of the first layer W_1. The controller may generate a thickness map including total thickness information of the first layer W_1 based on the first surface profile information, the second layer profile information, and the plurality of pieces of thickness information T1.

The controller may provide the data including the thickness information of the substrate to the substrate processing unit. For example, the controller may use the thickness information of the substrate to generate data required for the planarization process on the first layer W_1 of the substrate W. For example, the data required for the planarization process may include at least one of substrate thickness information, target thickness information, and target total thickness variation (TTV) information. However, aspects are not limited to the examples described above, and various information may be further included depending on the design.

Referring to FIGS. 7 and 8, the thickness map may be generated based on the thickness information of the first layer W_1 measured at the first points P1. The thickness information T1 of the first layer W_1 measured at the first points P1 may be measured at the respective locations of the first points P1. The planarization process by the substrate processing unit may be controlled according to the thickness information T1 of the substrate measured at the first points P1. The first points P1 may be planarized such that the thickness information T1 at the first points P1 of the substrate reaches the target thickness by the local planarization process.

The thickness of the first layer W_1 planarized at the first points P1 may be close to the target thickness. In order for the entire surface of the substrate to reach the target thickness, a planarization process for a non-planarized portion, for example, a planarization process for the second points P2 may be performed. Thickness information T2 of the substrate at the second points P2 may be measured for planarization of the second points P2.

After the planarization process is performed at the first points P1, an additional planarization process may be performed for the thickness distribution of the substrate. In this case, the operation of measuring the thickness of the region planarized at the first points P1 may be omitted. In order to take into account the thickness information T1 of the first points P1, thickness information T1′ of the substrate at the first points P1 may be estimated. That is, the planarization process may be performed without measuring the thickness of the substrate at the first points P1, by taking into account the thickness information T1′ estimated at the first points P1.

The thickness information T2 of the substrate may be measured at the second points P2 different from the first points P1. That is, the thickness information T2 of the substrate may be measured only at the second points P2. Since the first points P1 have a similar thickness to the target thickness, local planarization may be performed at the second points P2 and the entire region of the substrate W may be planarized.

In this way, while performing the planarization process of the substrate at the second points P2, the thickness measurement of the substrate W at the first points P1 may be omitted, but the efficiency of the planarization process may be improved by estimating the thickness information T1 at the first points P1.

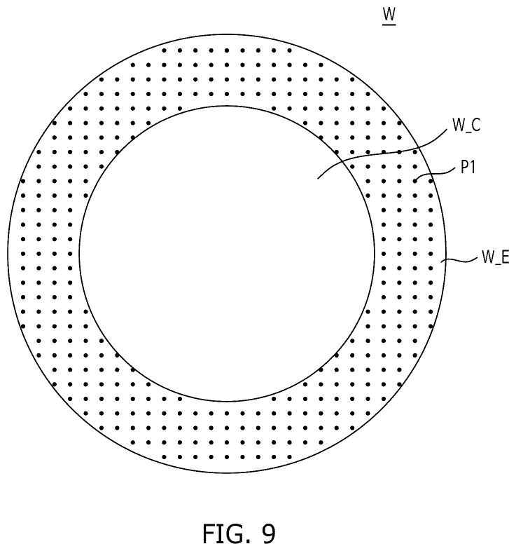

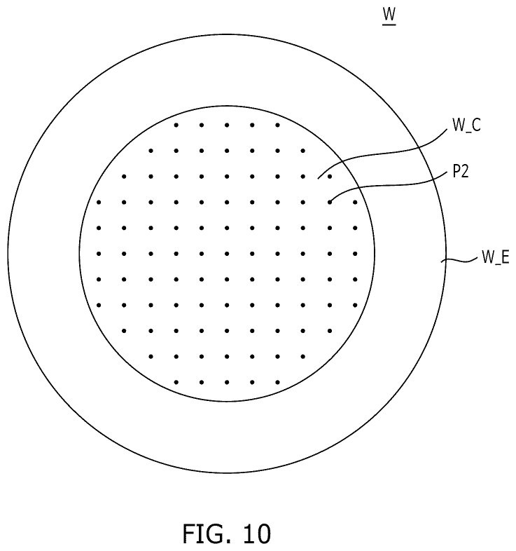

FIGS. 9 and 10 are diagrams provided to explain a method for measuring a thickness of a substrate.

Referring to FIGS. 9 and 10, the substrate W according to some aspects may have a plurality of points for measuring the thickness of the substrate or performing the planarization process. For example, the first points P1 may be positioned on the edge region W_E, and the second points P2 may be positioned on the center region W_C. This is only an example, and the first points P1 and the second points P2 may be distributed over the entire region of the substrate W. The first points P1 and the second points P2 may be disposed in the center region W_C and the edge region W_E, respectively.

The first points P1 positioned on the edge region W_E and the second points P2 positioned on the center region W_C may be disposed at regular gaps. The gaps between the second points P2 may be wider than the gaps between the first points P1. The number of second points P2 may be less than the number of first points P1. That is, the density of the first points P1 may be greater than the density of the second points P2.

In another aspect, the first points P1 and the second points P2 may be disposed at regular gaps on the substrate W and distributed over the entire region of the substrate W. That is, the first points P1 and the second points P2 may be disposed in various distributions as long as they are points at different positions.

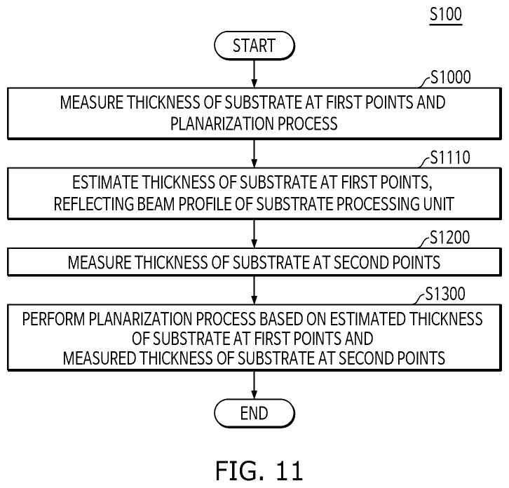

FIGS. 11 to 13 are flowcharts provided to explain a method for locally planarizing the substrate according to some aspects. Referring to FIGS. 11 to 13, the method for locally planarizing the substrate, in particular, a method for estimating the thickness of the substrate at the first points will be described. The same or similar operations to those of the method for locally planarizing the substrate described above with reference to FIG. 4 may be given the same reference numerals, and detailed descriptions thereof may be omitted.

Referring to FIG. 11, the method for locally planarizing the substrate according to some aspects may include an operation S1110 of estimating the thickness of the substrate at the first points, reflecting a beam profile.

The controller may estimate the thickness of the substrate at the first points based on a profile of a laser beam used in the substrate processing unit. After the planarization process at the first points is performed, the thickness of the substrate at the first points may decrease. The controller may calculate, from the beam profile used in the substrate processing unit, an amount removed from the substrate at the first points. For example, the amount removed from the substrate may be calculated from a type of the beam, intensity of the beam, scan speed, etc. In this way, the controller may estimate the thickness of the substrate at the first points, and take into account the estimated thickness of the substrate at the first points in the thickness estimation and planarization process at the second points.

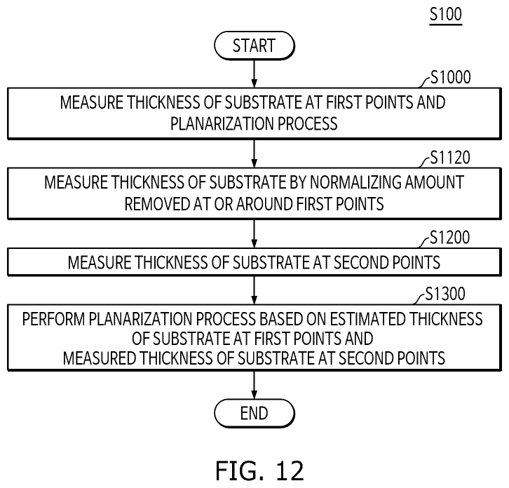

Referring to FIG. 12, the method for locally planarizing the substrate may include an operation S1120 of normalizing the amount removed at or around the first points to estimate the thickness of the substrate.

The controller may collect the data on the amount removed at or around the first points. The controller may fit the data on the amount removed at or around the first points according to a Gaussian distribution. Based on the normalized data, the amount removed at or around the first points may be reflected in the thickness estimation and planarization process at the second points.

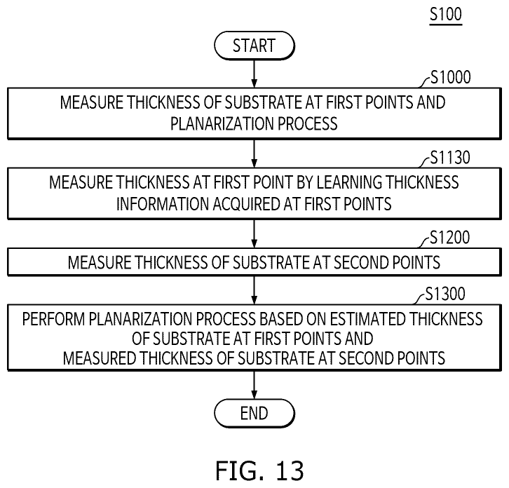

Referring to FIG. 13, the method for locally planarizing the substrate according to some aspects may include an operation S1130 of training the thickness information of the substrate acquired at the first points to estimate the thickness of the substrate at the first points. Machine learning may be used as the training method according to some aspects.

The controller may collect the data on the thickness information of the substrate acquired at the first points. For example, the controller may collect thickness gradient data of the substrate. The controller may appropriately preprocess the acquired data according to the selected learning model and train the learning model with the preprocessed data. The performance of the trained model may be evaluated using an R² score, etc., and a feedback loop, etc. may be configured to minimize the difference from the actual result. The controller may estimate the thickness of the substrate at the first points based on the data trained by using machine learning and may take into account the estimated thickness in the thickness estimation and planarization process at the second points.

Hereinbelow, a substrate processing apparatus according to another aspect will be described. The same or similar configurations will be given the same reference numerals, and detailed description thereof may be omitted.

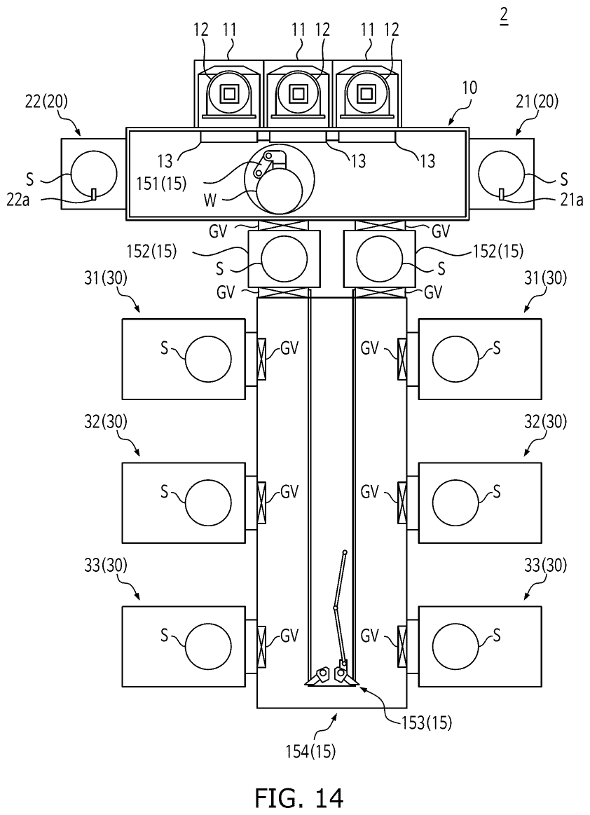

FIG. 14 is a diagram provided to explain a substrate processing apparatus. The same or similar configurations as those of the substrate processing apparatus described above with reference to FIG. 1 may be given the same reference numerals, and detailed descriptions thereof may be omitted.

Referring to FIG. 14, a substrate processing apparatus 2 according to some aspects may include the substrate processing unit 30.

The substrate processing unit 30 may provide a space for processing the substrate W. The substrate processing unit 30 may perform substrate processing such as planarization, etching, ashing, ion implantation, thin film deposition, cleaning, etc., but is not limited thereto. The substrate processing unit 30 may be disposed on one side of the transfer base 154. Each substrate processing unit 30 may include a stage S on which the substrate W transferred by the transfer arm 153 is seated. The substrate W may be processed while seated on the stage S.

The substrate processing unit 30 may include the first substrate processing unit 31, the second substrate processing unit 32, and a third substrate processing unit 33, which may perform different processes from each other. For example, the first substrate processing unit 31 may perform the planarization process, and the second substrate processing unit 32 and the third substrate processing unit 33 may perform the cleaning process. However, aspects are not limited thereto, and the substrate processing unit 30 may perform other unit processes or perform two or more unit processes.

The substrate W may be moved between the first substrate processing unit 31, the second substrate processing unit 32, or the third substrate processing unit 33 by the transfer arm 153 disposed on the transfer base 154. However, aspects are not limited thereto, and the substrate W may be moved to the loading unit 10, the measurement unit 20, etc., or may also be moved from the loading unit 10, the measurement unit 20, etc.

Each of the first substrate processing unit 31, the second substrate processing unit 32, and the third substrate processing unit 33 may include a plurality of substrate processing units. The first substrate processing unit 31, the second substrate processing unit 32, and the third substrate processing unit 33 may be disposed on both sides of the transfer base 154. However, aspects are not limited to the above, and the substrate processing unit 30 may be configured with more substrate processing units and may be arranged in various ways. Each of the first substrate processing unit 31, the second substrate processing unit 32, and the third substrate processing unit 33 may include two substrate processing units.

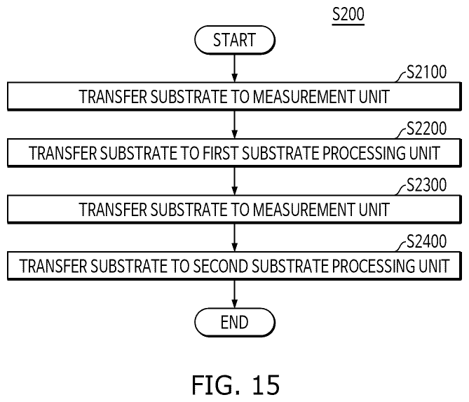

FIG. 15 is a diagram provided to explain a method for transferring the substrate.

Referring to FIG. 15, the method S200 for transferring the substrate may include first to fourth operations S2100, S2200, S2300, and S2400.

If the aspect is implemented differently, a specific sequence of the processes may be performed differently from the order described herein. For example, two processes described in succession may be performed substantially simultaneously or may be performed in the opposite order to the order described.

The method S200 may include an operation S2100 of transferring the substrate to the measurement unit. The substrate loaded into the loading unit may be transferred to the measurement unit for measurement of the surface state, position, thickness information, etc. of the substrate. The substrate may be moved from the loading unit to the measurement unit by the substrate transfer unit. The measurement unit may measure the surface state, thickness information, etc. of the substrate and transmit the measured result to the controller. The controller may generate a thickness map including a profile of the substrate and store the thickness information of the substrate, etc. at a plurality of points (e.g., first points) in the memory. Target thickness information of the substrate, etc. may be stored in the memory, and the processor may compare the thickness information of the substrate with the target thickness information of the substrate or with the target total thickness variation (TTV) to determine whether or not to perform the planarization process.

Upon determining whether to perform the planarization process, the controller may control the substrate transfer unit to transfer the substrate to the substrate processing unit. The controller may transfer the substrate from the measurement unit to the substrate processing unit.

The method S200 may include an operation S2200 of transferring the substrate to the first substrate processing unit. In the substrate processing apparatus according to some aspects, the first substrate processing unit may perform the planarization process. The controller may control the substrate transfer unit to transfer the substrate to the first substrate processing unit where the planarization process of the substrate is performed.

The first substrate processing unit may perform the planarization process on the transferred substrate. A method of irradiating a beam or using a polishing pad may be used in the planarization process. For example, in the first substrate processing unit, a local planarization process may be performed on the first points.

The method S200 may include an operation S2300 of transferring the substrate to the measurement unit. The substrate locally planarized at the first points may be transferred back to the measurement unit for measurement of the surface state, position, thickness information, etc. of the substrate. The substrate may be moved from the first substrate processing unit to the measurement unit by the substrate transfer unit. The measurement unit may measure the surface state, thickness information, etc. of the substrate and transmit the measured result to the controller. The controller may generate a thickness map including a profile of the substrate and store the thickness information of the substrate, etc. at a plurality of points (e.g., second points) in the memory. Target thickness information of the substrate, etc. may be stored in the memory, and the processor may compare the thickness information of the substrate with the target thickness information of the substrate or with the target total thickness variation (TTV) to determine whether or not to perform the planarization process.

That is, the controller may control the substrate transfer unit to transfer the substrate to the first substrate processing unit after the measurement unit measures the thickness at the first points of the substrate, and to transfer the substrate to the measurement unit after the substrate processing unit planarizes the substrate at the first points.

The controller may control the substrate transfer unit to transfer the substrate to the second substrate processing unit after the measurement unit measures the thickness of the substrate at the second points. Upon determining that the planarization of the substrate is sufficiently performed, the controller may control the substrate transfer unit such that other processes are performed on the substrate. That is, the controller may control the substrate transfer unit to transfer the substrate to the second substrate processing unit where the process other than the planarization process is performed. For example, the second substrate processing unit may perform the etching process.

The method S200 may include an operation S2400 of transferring the substrate to the second substrate processing unit. In the substrate processing apparatus according to some aspects, the second substrate processing unit may perform the etching process. The controller may control the substrate transfer unit to transfer to the second substrate processing unit where the etching process is performed. The second substrate processing unit may perform the etching process on the transferred substrate. For example, the etching process may be performed by a Reactive Ion Etching (RIE) method.

In some aspects, the method S200 for transferring the substrate according to some aspects may control the substrate transfer unit to transfer the substrate after the etching process to the measurement unit or to the third substrate processing unit.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the present disclosure has been described above by way of certain aspects and drawings, the present disclosure is not limited thereto, and it goes without saying that various changes and modifications can be made within the equivalent scope of the technical idea of the present disclosure and the claims to be described below by those of ordinary skill in the art.

1. A substrate processing apparatus comprising:
a substrate having first points and second points different from the first points;
a measurement module configured to measure at least one thickness of the substrate;
a substrate processor configured to perform a planarization process on the substrate; and
a controller configured to:
control the substrate processor to planarize the first points based on first thickness information of the substrate, the first thickness information including first thicknesses measured at the first points of the substrate by the measurement module, and
control the substrate processor to planarize the second points based on second thickness information of the substrate, the second thickness information including second thicknesses measured at the second points of the substrate by the measurement module.

2. The substrate processing apparatus according to claim 1, wherein the controller is configured to estimate third thicknesses at the first points in response to the substrate processor planarizing the first points of the substrate.

3. The substrate processing apparatus according to claim 2, wherein the controller is configured to control the substrate processor to planarize the second points based on the third thicknesses at the first points.

4. The substrate processing apparatus according to claim 2, wherein the controller is configured to estimate the third thicknesses at the first points based on a beam profile of the substrate processor.

5. The substrate processing apparatus according to claim 1, wherein the first points are positioned at an edge region of the substrate, and
wherein the second points are positioned at a center region of the substrate.

6. The substrate processing apparatus according to claim 5, wherein the first points are spaced apart from each other at distances that decrease in a direction away from a center of the substrate increases, and
wherein the second points are equally spaced apart from each other.

7. The substrate processing apparatus according to claim 5, wherein the first points and the second points are disposed in a grid form, and
wherein first distances between the first points are less than second distances between the second points.

8. The substrate processing apparatus according to claim 1, wherein the substrate processor is configured to planarize at least a portion of the substrate using a beam.

9. The substrate processing apparatus according to claim 1, wherein the substrate processor is configured to planarize at least a portion of the substrate using a polishing pad.

10. The substrate processing apparatus according to claim 1, further comprising a substrate transferer is configured to transfer the substrate,
wherein the controller is configured to:
in response to the measurement module measuring the first thicknesses at the first points, control the substrate transferer to transfer the substrate to the substrate processor, and in response to the substrate processor planarizing the first points of the substrate, control the substrate transferer to transfer the substrate to the measurement module.

11. The substrate processing apparatus according to claim 10, wherein the substrate processor is a first substrate processor, and
wherein the substrate processing apparatus further includes a second substrate processor configured to process the substrate, and
wherein the controller is configured to, in response to the measurement module measuring the second thicknesses at the second points, control the substrate transferer to transfer the substrate to the second substrate processor.

12. A substrate processing apparatus comprising:
a loader configured to receive a substrate having first points and second points different from the first points;
a measurement module connected to the loader and configured to measure first and second thickness information of the substrate loaded into the loader;
a substrate processor connected to the loader and configured to perform a planarization process using a beam on the substrate;
a substrate transferer configured to transfer the substrate from the loader to the measurement module or to the substrate processor; and
a controller configured to:
control a first time for planarizing the first points by the substrate processor based on the first thickness information of the substrate, the first thickness information including first thicknesses measured at the first points, and
control a second time for planarizing the second points by the substrate processor based on the second thickness information of the substrate, the second thickness information including second thicknesses measured at the second points.

13. The substrate processing apparatus according to claim 12, wherein the controller is configured to cause the first thicknesses of the substrate measured at the first points by the measurement module to be proportional to the first time for planarizing the first points by the substrate processor.

14. The substrate processing apparatus according to claim 13, wherein the controller is configured to cause the second thicknesses of the substrate measured at the second points by the measurement module to be proportional to the second time for planarizing the second points by the substrate processor.

15. The substrate processing apparatus according to claim 12, wherein the controller is configured to:
estimate third thicknesses at the first points in response to the substrate processor planarizing the first points of the substrate, and
planarize the second points of the substrate based on estimated third thicknesses at the first points.

16. The substrate processing apparatus according to claim 15, wherein the controller is configured to estimate the third thicknesses at the first points based on a beam profile of the substrate processor.

17. The substrate processing apparatus according to claim 12, wherein
the first points are positioned at an edge region of the substrate, and
wherein the second points are positioned at a center region of the substrate.

18. The substrate processing apparatus according to claim 17, wherein
the first points are spaced apart from each other at distances that decrease in a direction away from a center of the substrate increases, and
wherein the second points are equally spaced apart from each other.

19. A substrate processing apparatus, comprising:
a substrate having first points and second points different from the first points;
a measurement module configured to measure thickness information of the substrate;
a first substrate processor configured to perform a planarization process using a beam on the substrate;
a second substrate processor configured to process the substrate planarized by the first substrate processor; and
a controller configured to:
control a first time for planarizing the first points by the substrate processor based on first thickness information of the substrate, the first thickness information including first thicknesses measured at the first points, and
control a second time for planarizing the second points by the substrate processor based on second thickness information of the substrate and estimated thickness information of the substrate, the second thickness information including second thicknesses measured at the second points, and the estimated thickness information including third thicknesses estimated at the first points.

20. The substrate processing apparatus according to claim 19, further comprising
a substrate transferer configured to transfer the substrate to at least one of the measurement module, the first substrate processor, or the second substrate processor,
wherein the controller is configured to:
control the substrate transferer to transfer the substrate to the first substrate processor in response to the measurement module measuring the first thicknesses of the substrate at the first points, and to transfer the substrate to the measurement module in response to the substrate processor planarizing the substrate at the first points, and
control the substrate transferer to transfer the substrate to the second substrate processor in response to the measurement module measuring the second thicknesses of the substrate at the second points.
